(19) United States
(12) Patent Application Publication
(10) Pub. No.: US 2026/0040954 A1
(43) Pub. Date: Feb. 5, 2026

(54) MEMORY DEVICE INCLUDING ALIGNMENT KEY

(71) Applicant: SK hynix Inc., Gyeonggi-do (KR)

(72) Inventor: Heon Yong CHANG, Gyeonggi-do (KR)

(21) Appl. No.: 18/963,765

(22) Filed: Nov. 29, 2024

(30) Foreign Application Priority Data
Jul. 31, 2024 (KR) 10-2024-0101419

(51) Int. Cl. H01L 23/544; H10D 64/01; H10D 64/27

(52) U.S. Cl. CPC H01L 23/544; H10D 64/017; H10D 64/518; H01L 2223/54426

(57) ABSTRACT

A memory device may include a substrate, a lower electrode disposed on the substrate in a chip region, an upper electrode on the lower electrode, a dielectric layer disposed between the lower electrode and the upper electrode, a dummy upper electrode disposed over the substrate in a scribe lane region continuous with the chip region, and disposed at a level higher than an upper surface of the lower electrode, and an alignment key disposed on the dummy upper electrode.

### CROSS-REFERENCE TO RELATED APPLICATION

The present application claims priority under 35 U.S.C. 119 (a) to Korean patent application number 10-2024-0101419 filed on Jul. 31, 2024, which is incorporated herein by reference in its entirety.

### TECHNICAL FIELD

Embodiments of the present disclosure relate to a memory device including an alignment key.

### BACKGROUND

A memory device is an important component in the electronics industry owing to their characteristics such as miniaturization, multi-functionality, and/or low manufacturing cost. As the electronics industry develops, memory devices are gradually becoming more highly integrated.

As a memory device becomes more highly integrated, the size of a memory chip becomes smaller. In order to implement the smaller memory chip, a micro pattern may be used in the memory chip manufacturing process. Since the micro pattern is small in size, and even a small error during the manufacturing process may cause a defect in the memory device, an alignment key may be used to align the micro patterns.

### SUMMARY

Embodiments of the present disclosure may provide a memory device capable of preventing the deterioration of device characteristics due to process defects.

Embodiments of the present disclosure may provide a memory device including a substrate, a lower electrode disposed on the substrate in a chip region, an upper electrode on the lower electrode, a dielectric layer disposed between the lower electrode and the upper electrode, a dummy upper electrode disposed over the substrate in a scribe lane region continuous with the chip region, and disposed at a level higher than an upper surface of the lower electrode, and an alignment key disposed on the dummy upper electrode.

Embodiments of the present disclosure may provide a memory device including a substrate, a lower electrode disposed on the substrate in a chip region, an upper electrode on the lower electrode, a dielectric layer disposed between the lower electrode and the upper electrode, and an alignment key disposed over the substrate scribe lane region continuous with the chip region, and positioned at a level higher than an upper surface of the lower electrode.

Embodiments of the present disclosure may provide a memory device including a substrate, a lower electrode disposed on the substrate in a chip region, an upper electrode on the lower electrode, a dielectric layer disposed between the lower electrode and the upper electrode, a support layer disposed on the substrate in a scribe lane region continuous with the chip region, a dummy upper electrode disposed on the support layer, and an alignment key disposed on the dummy upper electrode.

According to embodiments of the present disclosure, it is possible to prevent the deterioration of device characteristics of a memory cell due to process defects.

### BRIEF DESCRIPTION OF THE DRAWINGS

FIG. 1 illustrates a planar structure of a memory device according to embodiments of the present disclosure.

FIG. 2 is an enlarged drawing of a part of FIG. 1.

FIG. 3 illustrates a cross-sectional structure of a part I-I′ of FIG. 2.

FIG. 4 illustrates another embodiment of FIG. 2.

FIG. 5 illustrates a cross-sectional structure of a part II-II′ of FIG. 4.

FIGS. 6 to 13 illustrate a method for forming a memory device according to embodiments of the present disclosure.

FIGS. 14 and 15 illustrate other methods for forming a memory device according to embodiments of the present disclosure.

### DETAILED DESCRIPTION

Hereinafter, various embodiments of the present disclosure will be described in detail with reference to accompanying drawings.

In the attached drawings, two directions parallel to an upper surface of a substrate are defined as a first direction FD and a second direction SD, respectively, and a direction protruding vertically from the upper surface of the substrate is defined as a third direction VD. The first direction FD and the second direction SD may be substantially perpendicular to each other. The third direction VD may be a direction perpendicular to the first direction FD and the second direction SD. In the following specification, ‘vertical’ or ‘vertical direction’ will be used to have substantially the same meaning as the third direction VD. The direction indicated by an arrow in the drawings and its opposite direction may indicate the same direction.

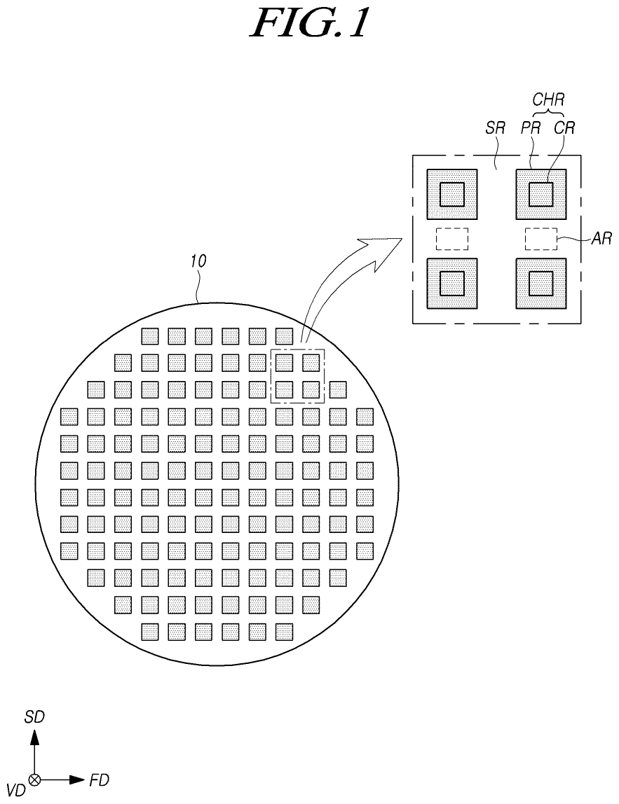

FIG. 1 illustrates a planar structure of a memory device according to embodiments of the present disclosure.

Referring to FIG. 1, a wafer 10 may include a plurality of chip regions CHR and a scribe lane region SR.

The chip regions CHRs may be regions where individual memory chips are formed after the wafer 10 is diced. Integrated circuits for functioning as individual memory chips may exist in each chip region CHR. The chip region CHR may include a cell region CR where a memory cell is arranged, and a peripheral region PR where a circuit for transmitting various signals to the memory cell is arranged on the outside of the cell region CR.

The scribe lane region SR may extend in the first direction FD and the second direction SD to intersect each other so as to surround the side surfaces of each chip region CHR. The scribe lane region SR may be continuous with the chip region CHR. The wafer 10 may be diced along a cutting line in the scribe lane region SR by a laser, a blade, or the like in a dicing process. The scribe lane region SR may include an alignment key region AR. The alignment key region AR may be defined as a region where an alignment key is disposed. The alignment key region AR may be located between adjacent chip regions CHR. Although the alignment key region AR is illustrated in FIG. 1 as being located between chip regions CHR adjacent to each other in the second direction SD, the location of the alignment key region AR is not limited thereto.

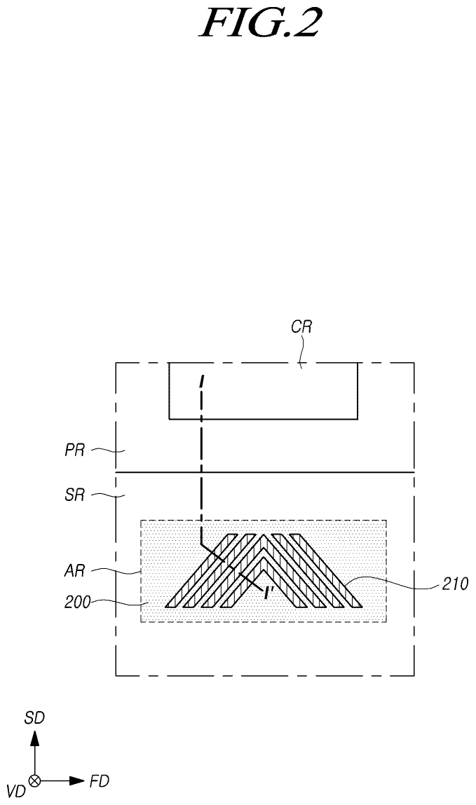

FIG. 2 is an enlarged drawing of a part of FIG. 1.

Referring to FIG. 2, a dummy upper electrode 200 and an alignment key 210 may be disposed in the alignment key region AR.

In FIG. 2, for convenience, the dummy upper electrode 200 is illustrated as being arranged within the alignment key region AR, but the embodiments are not limited thereto. That is, the dummy upper electrode 200 may extend further to the outside of the alignment key region AR in the first direction FD or the second direction SD.

The alignment key 210 may be disposed on the dummy upper electrode 200 within the alignment key region AR. The alignment key 210 may be used for aligning a plurality of masks used in the manufacturing process of a memory device.

In the illustrated embodiment of FIG. 2, the alignment key 210 may be disposed in a line shape on a plane defined by the first direction FD and the second direction SD. The alignment keys 210 having a line shape may be arranged spaced apart from each other within the alignment key region AR. However, this is only an example, and the shape and arrangement structure of the alignment keys 210 are not limited thereto. That is, the alignment keys 210 may have a different shape than that shown in FIG. 2 and may be arranged in a different structure in order to perform the alignment function.

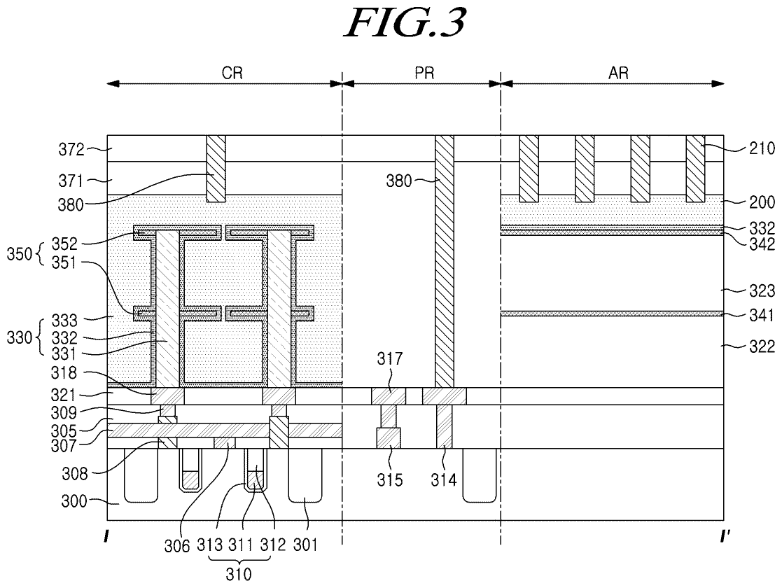

FIG. 3 illustrates a cross-sectional structure of a part I-I′ of FIG. 2.

Referring to FIG. 3, a memory device may include a substrate 300, a device isolation layer 301, a gate structure 310, an isolation insulating layer 305, a bit line contact 306, a bit line 307, a lower contact plug 308, an upper contact plug 309, a contact 314, and a gate 315. Further, the memory device may include a first insulating layer 321, a wiring 317, a landing pad 318, a capacitor 330, a first support layer 341, a second support layer 342, a support pattern layer 350, a first interlayer insulating layer 371, a second interlayer insulating layer 372, a through contact 380, a dummy upper electrode 200, and an alignment key 210.

The substrate 300 may include a semiconductor substrate such as a silicon wafer or a silicon-on-insulator (SOI) wafer. The substrate 300 may include a III-V group semiconductor substrate, for example, a compound semiconductor substrate such as GaAs. The substrate 300 may include single crystal silicon, polysilicon, amorphous silicon, single crystal silicon germanium, polycrystalline silicon germanium, carbon-doped silicon, or a combination thereof.

The substrate 300 may include at least one device isolation layer 301 in each of the cell region CR and the peripheral region PR. In the illustrate example of FIG. 3, the substrate 300 may include two device isolation layers 301 in the cell region CR and one device isolation layers 301 in the peripheral region PR. But the number of device isolation layers is not limited thereto. The device isolation layer 301 may be formed using a trench device isolation technology such as shallow trench isolation (STI). The device isolation layer 301 may include silicon oxide, silicon nitride, silicon oxynitride, a low-K dielectrics, a high-K dielectrics, or a combination thereof.

In the cell region CR, a gate structure 310 may be embedded in the substrate 300. The gate structure 310 may include a word line 311, a gate capping layer 312, and a gate insulating layer 313. An upper surface of the word line 311 may be located at a lower level than an upper surface of the substrate 300. The word line 311 may be a buried gate or a buried word line. The gate capping layer 312 may be disposed on the word line 311. The gate insulating layer 313 may surround the side surfaces of the word line 311 and the gate capping layer 312.

The word line 311 may include a conductive material such as a metal, a metal oxide, a metal nitride, a metal silicide, polysilicon, a conductive carbon, or a combination thereof. The gate capping layer 312 may include silicon oxide, silicon nitride, silicon oxynitride, a low-k dielectric, a high-k dielectric, or a combination thereof. The gate insulating layer 313 may include silicon oxide, silicon nitride, silicon oxynitride, a high-k dielectric, or a combination thereof.

In the cell region CR, the bit line contact 306, the contact plugs 308 and 309, and the isolation insulating layer 305 may be disposed on the substrate 300. The bit line 307 may be disposed on the bit line contact 306. The bit line 307 may be arranged in a direction perpendicular to the word line 311. For example, when the bit line 307 is disposed in the first direction FD, the word line 311 may be arranged in the second direction SD. The bit line 307 may be separated from the contact plugs 308 and 309. That is, in some embodiments, an insulating layer may be further disposed to insulate between the bit line 307 and the contact plugs 308 and 309. The landing pad 318 and the first insulating layer 321 may be disposed on the upper contact plug 309. The landing pad 318 may overlap with the upper contact plug 309 in the vertical direction VD.

The isolation insulating layer 305 and the first insulating layer 321 may include silicon oxide, silicon nitride, silicon oxynitride, a low-K dielectrics, a high-K dielectrics, or a combination thereof.

The bit line contact 306, the bit line 307, the contact plugs 308 and 309, and the landing pad 318 may include a conductive material such as a metal, a metal oxide, a metal nitride, a metal silicide, polysilicon, conductive carbon, or a combination thereof.

In the cell region CR, a lower electrode 331, a dielectric layer 332, an upper electrode 333, the support pattern layer 350, the first interlayer insulating layer 371, the second interlayer insulating layer 372, and the through contact 380 may be disposed on the first insulating layer 321 and the landing pad 318. The lower electrode 331, the dielectric layer 332, and the upper electrode 333 may form the capacitor 331 of the memory cell. In some embodiments, an etch stop layer may be further disposed between the first insulating layer 321 and the dielectric layer 332.

The lower electrode 331 may overlap with the landing pad 318 in a vertical direction. The support pattern layer 350 is disposed on a side wall of the lower electrode 331. The support pattern layer 350 may surround the side surface of the lower electrode 331. The support pattern layer 350 may include a first support pattern layer 351 and a second support pattern layer 352 on the first support pattern layer 351.

The dielectric layer 332 may be disposed to cover the surfaces of the lower electrode 331 and the support pattern layer 350.

The upper electrode 333 may be disposed on the dielectric layer 332. An upper surface of the upper electrode 333 may be located at a higher level than an upper surface of the lower electrode 331.

The first interlayer insulating layer 371 may be disposed on the upper electrode 333. The second interlayer insulating layer 372 may be disposed on the first interlayer insulating layer 371. The through contact 380 may penetrate the second interlayer insulating layer 372 and the first interlayer insulating layer 371 to contact the upper surface of the upper electrode 333.

The lower electrode 331, the upper electrode 333, and the through contact 380 may include a conductive material such as a metal, a metal oxide, a metal nitride, a metal silicide, polysilicon, conductive carbon, or a combination thereof. In one embodiment, the upper electrode 333 may include titanium nitride or silicon germanium.

The support pattern layer 350 may include, but is not limited to, silicon nitride or silicon carbon nitride. The dielectric layer 332 may include a high-k dielectric material, silicon oxide, silicon nitride, or a combination thereof. The first and second interlayer insulating layers 371 and 372 may include oxide.

In the peripheral region PR, the contact 314 and the gate 315 may be disposed on the substrate 300. The wiring 317 and the first insulating layer 321 may be disposed on the contact 314. The wiring 317 may overlap with the contact 314 in a vertical direction. In one embodiment, the contact 314 and the gate 315 may be source/drain electrodes and gate electrodes of transistors constituting various circuits located in the peripheral region PR, respectively. The contact 314, the gate 315, and the wiring 317 may include a conductive material such as a metal, a metal oxide, a metal nitride, a metal silicide, polysilicon, conductive carbon, or a combination thereof.

In the peripheral region PR, the first interlayer insulating layer 371, the second interlayer insulating layer 372, and the through contact 380 may be disposed on the first insulating layer 321 and the wiring 317. The second interlayer insulating layer 372 may be disposed on the first interlayer insulating layer 371. The through contact 380 may penetrate the second interlayer insulating layer 372 and the first interlayer insulating layer 371 to contact an upper surface of at least one of the wirings 317.

In the alignment key region AR, the isolation insulating layer 305 may be disposed on the substrate 300. The first insulating layer 321 may be disposed on the isolation insulating layer 305.

In the alignment key region AR, the second insulating layer 322 may be disposed on the first insulating layer 321. The first support layer 341 may be disposed on the second insulating layer 322. The third insulating layer 323 may be disposed on the first support layer 341. The second support layer 342 may be disposed on the third insulating layer 323. The first support layer 341 and the second support layer 342 may be disposed on the same layer as the first support pattern layer 351 and the second support pattern layer 352, respectively. In one embodiment, the first support pattern layer 351 and the second support pattern layer 352 may be formed by etching a portion of the first support layer 341 and the second support layer 342, respectively.

The second insulating layer 322 and the third insulating layer 323 may include oxide, but are not limited thereto. The first support layer 341 and the second support layer 342 may include silicon nitride or silicon carbonitride. The first support pattern layer 351 may include the same material as the material forming the first support layer 341. The second support pattern layer 352 may include the same material as the material forming the second support layer 342.

In the alignment key region AR, the dielectric layer 332 may be disposed on the second support layer 342. The dummy upper electrode 200 may be disposed on the dielectric layer 332. A lower surface of the dummy upper electrode 200 may be located at a level higher than an upper surface of the lower electrode 331 disposed in the cell region CR. An upper surface of the dummy upper electrode 200 may form substantially the same plane as the upper surface of the upper electrode 333 arranged in the cell region CR.

In an embodiment, the dummy upper electrode 200 may be in the form of a two-dimensional plate. That is, as illustrated in FIG. 2, the dummy upper electrode 200 may be disposed to cover part or all of the alignment key region AR on a plane defined by the first direction FD and the second direction SD.

In one embodiment, the dummy upper electrode 200 may be formed in the same process as the upper electrode 333. The dummy upper electrode 200 may include the same material as the material forming the upper electrode 333. In one embodiment, the dummy upper electrode 200 may include titanium nitride or silicon germanium.

The first interlayer insulating layer 371, the second interlayer insulating layer 372, and the alignment key 210 may be disposed on the dummy upper electrode 200. The alignment key 210 may penetrate the second interlayer insulating layer 372 and the first interlayer insulating layer 371 in the vertical direction to contact an upper surface of the dummy upper electrode 200. The alignment key 210 may be disposed spaced apart from each other on the dummy upper electrode 200.

In the illustrated embodiment of FIG. 3, the alignment key 210 may extend into the inside of the dummy upper electrode 200 in the vertical direction. In this embodiment, a lower surface of the alignment key 210 may be located at a level lower than the upper surface of the dummy upper electrode 200. In addition, a portion of the side surface of the alignment key 210 may contact the dummy upper electrode 200.

In an embodiment, the alignment key 210 may be formed in the same process as the through contact 380. In one embodiment, the alignment key 210 may include the same material as a material forming the through contact 380. The alignment key 210 may include a conductive material, such as a metal, a metal oxide, a metal nitride, a metal silicide, polysilicon, conductive carbon, or a combination thereof.

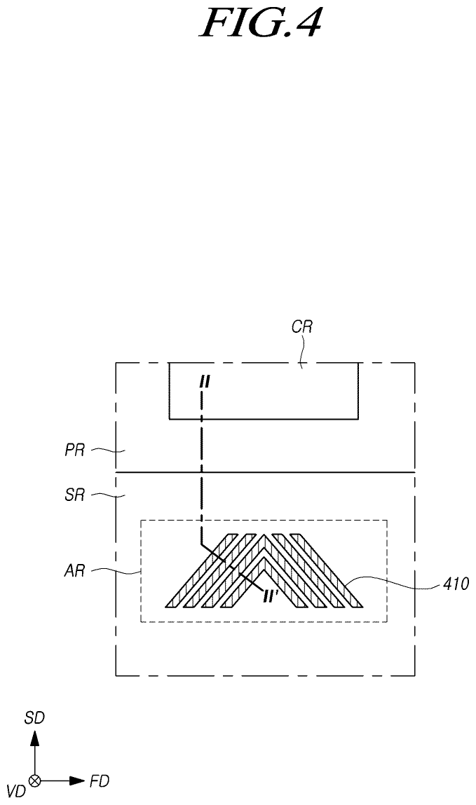

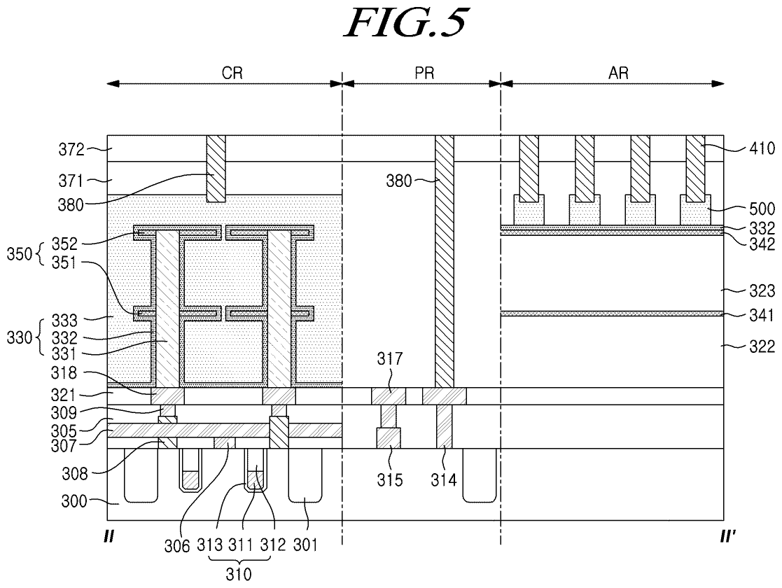

FIG. 4 illustrates another embodiment of FIG. 2. FIG. 5 illustrates a cross-sectional structure of a part II-II′ of FIG. 4.

In describing the following embodiments of FIGS. 4 and 5, descriptions will be omitted of a configuration substantially the same as that of the previous embodiments FIGS. 2 and 3.

Referring to FIGS. 4 and 5, a memory device may include a substrate 300, a device isolation layer 301, a gate structure 310, an isolation insulating layer 305, a bit line contact 306, a bit line 307, a lower contact plug 308, an upper contact plug 309, a contact 314, and a gate 315. Further, the memory device may include a first insulating layer 321, a wiring 317, a landing pad 318, a capacitor 330, a first support layer 341, a second support layer 342, a support pattern layer 350, a first interlayer insulating layer 371, a second interlayer insulating layer 372, a through contact 380, a dummy upper electrode 500, and an alignment key 410.

In the alignment key region AR, the first insulating layer 321, the second insulating layer 322, the first support layer 341, a third insulating layer 323, the second support layer 342, and a dielectric layer 332 may be sequentially disposed on the substrate 300.

The first interlayer insulating layer 371 and the dummy upper electrode 500 may be disposed on the dielectric layer 332. In one embodiment, the dummy upper electrode 500 may be disposed on a portion of the dielectric layer 332. The dummy upper electrode 500 may expose at least a portion of an upper surface of the dielectric layer 332.

In the illustrated embodiment of FIGS. 4 and 5, the dummy upper electrode 500 may be disposed along a shape in which the alignment key 410 is arranged on a plane defined by the first direction FD and the second direction SD. As illustrated in FIG. 4, when the alignment keys 410 are disposed in a line shape spaced apart from each other, the dummy upper electrode 500 may be disposed to overlap with the alignment key 410 along a path along which the alignment keys 410 are disposed. The dummy upper electrode 500 may be disposed to correspond to each of the line-shaped alignment keys 410. A width of the dummy upper electrode 500 may be the same as that of the alignment key 410, or may be greater than that of the alignment key 410.

In an embodiment, the dummy upper electrode 500 may be formed by removing a portion of a dummy upper electrode 200 after the dummy upper electrode 200 described with reference to FIG. 3 is formed. In one embodiment, the process of removing a portion of the dummy upper electrode 200 may include an etching process.

The dummy upper electrode 500 may include the same material as a material forming the upper electrode 333. In an embodiment, the dummy upper electrode 500 may include titanium nitride or silicon germanium.

The second interlayer insulating layer 372 may be disposed on the dummy upper electrode 500 and the first interlayer insulating layer 371. The alignment key 410 may penetrate the second interlayer insulating layer 372 and the first interlayer insulating layer 371 in the vertical direction to contact an upper surface of the dummy upper electrode 500.

In an embodiment, the alignment key 410 may extend into the inside of the dummy upper electrode 500 in the vertical direction. In this embodiment, a lower surface of the alignment key 410 may be located at a level lower than the upper surface of the dummy upper electrode 500. In addition, a portion of the side surface of the alignment key 410 may contact the dummy upper electrode 500.

In one embodiment, the alignment key 410 may be formed in the same process as the through contact 380. The alignment key 410 may include the same material as the material forming the through contact 380. The alignment key 410 may include a conductive material, such as a metal, a metal oxide, a metal nitride, a metal silicide, polysilicon, conductive carbon, or a combination thereof.

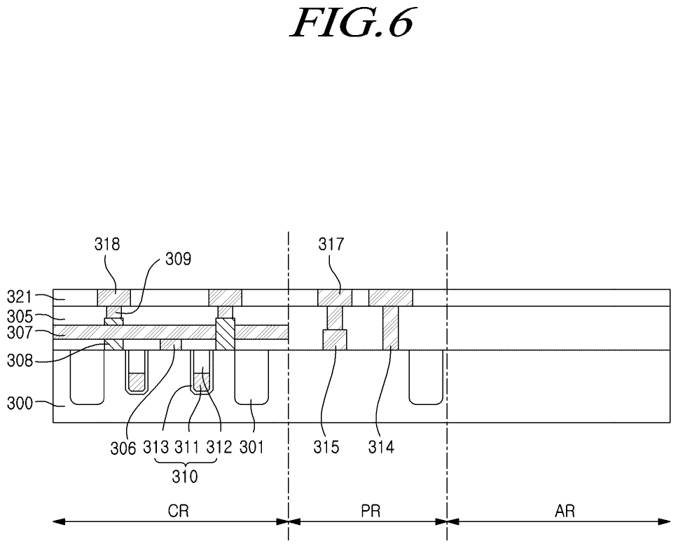

FIGS. 6 to 13 illustrate a method for forming a memory device according to embodiments of the present disclosure.

Referring to FIG. 6, a device isolation layer 301 and a gate structure 310 may be formed within a substrate 300. An isolation insulating layer 305, a bit line contact 306, a bit line 307, a lower contact plug 308, an upper contact plug 309, a contact 314, and a gate 315 may be formed on the substrate 300. A wiring 317 and a landing pad 318 may be formed on the isolation insulating layer 305, the contact 314, and the upper contact plug 309.

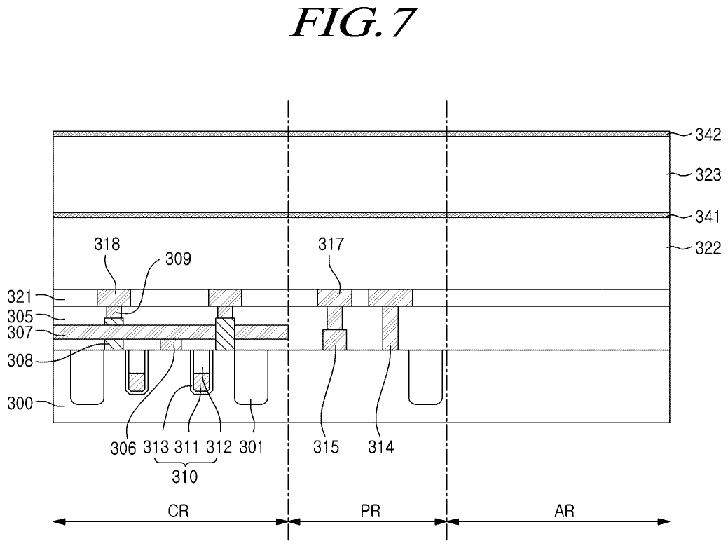

Referring to FIG. 7, a second insulating layer 322 may be formed on the landing pad 318 and the first insulating layer 321 in a cell region CR, on the wiring 317 and the first insulating layer 321 in the peripheral region PR, and on the first insulating layer 321 in the alignment key region AR. In one embodiment, an etch stop layer may be formed on the first insulating layer 321. The etch stop layer may serve to protect the first insulating layer 321 and layers disposed below the first insulating layer 321 during a subsequent etching process. The second insulating layer 322 may be formed on the etch stop layer. A first support layer 341 may be formed on the second insulating layer 322. A third insulating layer 323 may be formed on the first support layer 341. A second support layer 342 may be formed on the third insulating layer 323.

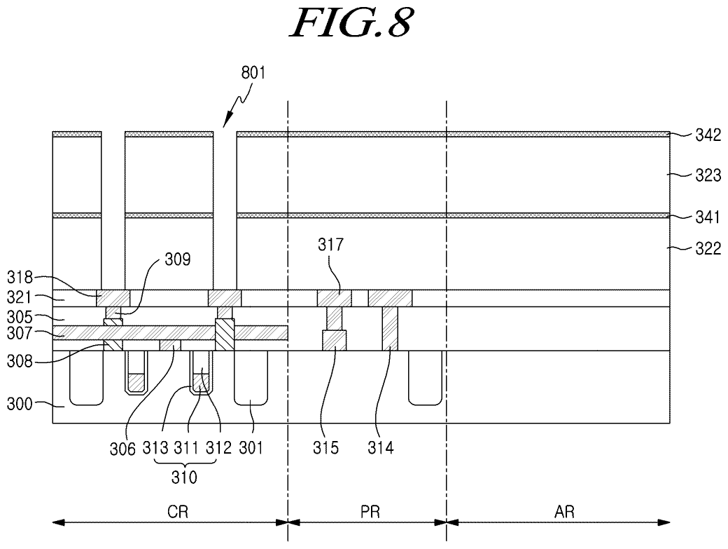

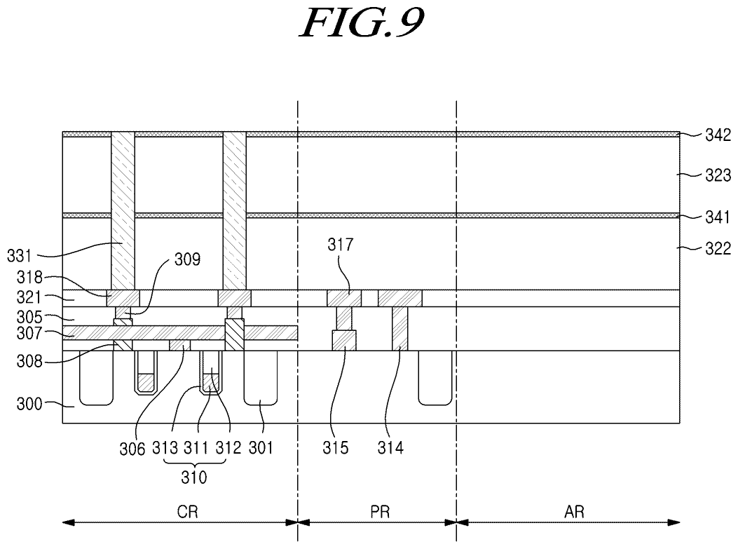

Referring to FIGS. 8 and 9, a through hole 801 penetrating the second support layer 342, the third insulating layer 323, the first support layer 341, and the second insulating layer 322 may be formed in the cell region CR. In an embodiment, the through hole 801 may be formed through an anisotropic etching. The through hole 801 formed in the cell region CR may expose an upper surface of the landing pad 318. A lower electrode 331 may be formed within the through hole 801.

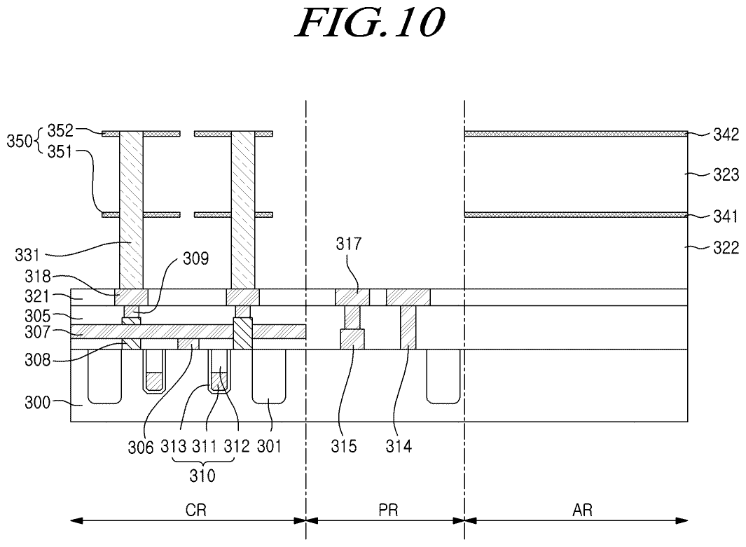

Referring to FIG. 10, a portion of the first support layer 341 and the second support layer 342 may be removed in the cell region CR. In the peripheral region PR, both the first support layer 341 and the second support layer 342 may be removed. In the cell region CR, a first support pattern layer 351 and a second support pattern layer 352 may be formed as a portion of the first support layer 341 and the second support layer 342 are removed. The first support pattern layer 351 and the second support pattern layer 352 each may surround a side surface of the lower electrode 331.

After the first support pattern layer 351 and the second support pattern layer 352 are formed, there may be removed the second insulating layer 322 and the third insulating layer 323 located in the cell region CR and the peripheral region PR. The second insulating layer 322 and the third insulating layer 323 may be removed by a dip-out process. In one embodiment, the dip-out process may be a wet etching process.

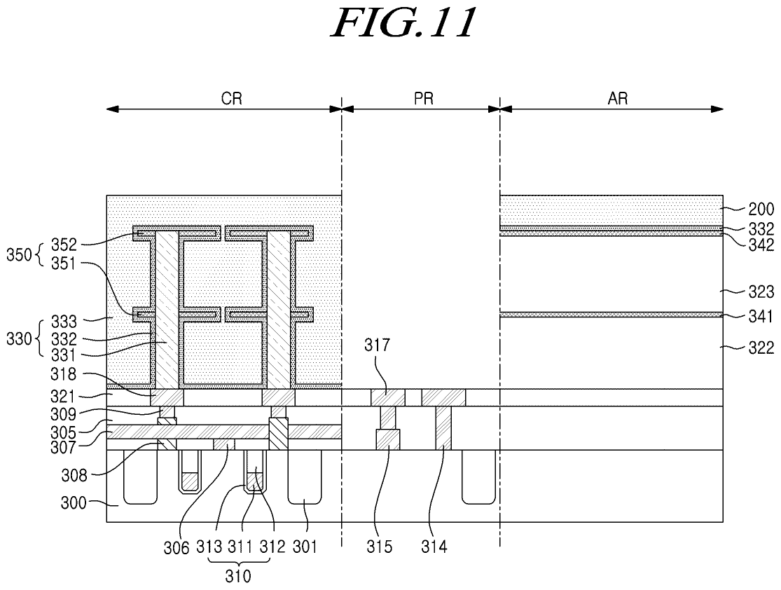

Referring to FIG. 11, a dielectric layer 332 may be formed on the first insulating layer 321, the lower electrode 331, and the support pattern layer 350 in the cell region CR, and on the second support layer 342 in the alignment key region AR. In the cell region CR, the dielectric layer 332 may be formed along a profile of the surface of the lower electrode 331 and the support pattern layer 350.

In the cell region CR, an upper electrode 333 may be formed on the dielectric layer 332. In the alignment key region AR, a dummy upper electrode 200 may be formed on the dielectric layer 332. In one embodiment, the dummy upper electrode 200 may include the same material as a material forming the upper electrode 333. In the peripheral region PR, the dielectric layer 332 and the upper electrode 333 may be removed. In one embodiment, an upper surface of the dummy upper electrode 200 may be located at substantially the same level as an upper surface of the upper electrode 333.

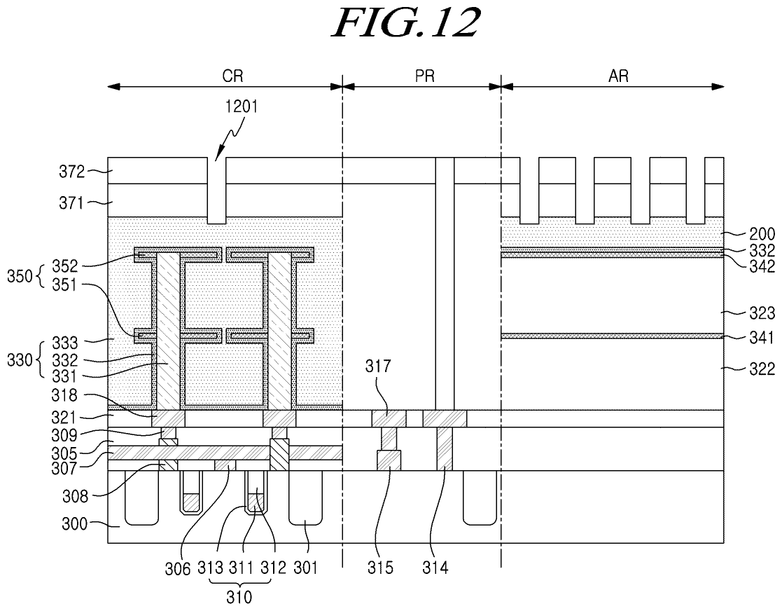

Referring to FIG. 12, a first interlayer insulating layer 371 may be formed on the upper electrode 333 in the cell region CR, on the first insulating layer 321 and the wiring 317 in the peripheral region PR, and on the dummy upper electrode 200 in the alignment key region AR. A second interlayer insulating layer 372 may be formed on the first interlayer insulating layer 371.

A through hole 1201 may be formed to penetrate the second interlayer insulating layer 372 and the first interlayer insulating layer 371 in the cell region CR, the peripheral region PR, and the alignment key region AR in the vertical direction. The through hole 1201 formed in the cell region CR may expose an upper surface of the upper electrode 333. In one embodiment, the through hole 1201 may extend into the inside of the upper electrode 333 in the vertical direction. In the above embodiment, one end of the through hole 1201 may be positioned at a level lower than the upper surface of the upper electrode 333. The through hole 1201 formed in the peripheral region PR may expose an upper surface of the wiring 317. In one embodiment, the through hole 1201 may extend into the inside of the wiring 317 in the vertical direction. In the above embodiment, one end of the through hole 1201 may be positioned at a level lower than the upper surface of the wiring 317. The through hole 1201 formed in the alignment key region AR may expose the upper surface of the dummy upper electrode 200. In one embodiment, the through hole 1201 may extend into the inside of the dummy upper electrode 200 in the vertical direction. In this embodiment, one end of the through hole 1201 may be positioned at a level lower than the upper surface of the dummy upper electrode 200.

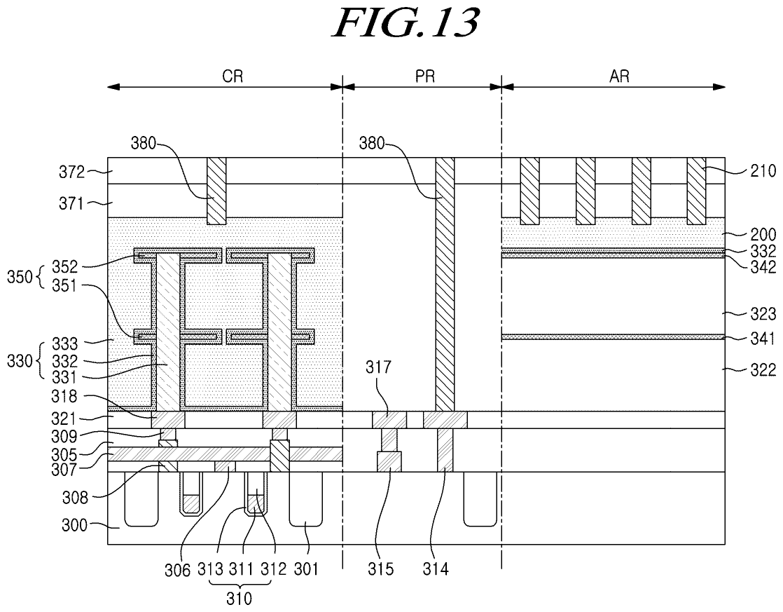

Referring to FIG. 13, the through contact 380 in the cell region CR and the peripheral region PR may be disposed to fill the through hole 1201. In the cell region CR, a lower surface of the through contact 380 may contact an upper surface of the upper electrode 333. Alternatively, in one embodiment, when the through contact 380 extends vertically into the upper electrode 333, the lower surface and a portion of the side surface of the through contact 380 may contact the upper electrode 333. In the peripheral region PR, the lower surface of the through contact 380 may contact an upper surface of the wiring 317. Alternatively, in one embodiment, when the through contact 380 extends vertically into the wiring 317, the lower surface and a portion of the side surface of the through contact 380 may contact the wiring 317.

In the alignment key region AR, the alignment key 210 may be disposed to fill the through hole 1201. The lower surface of the alignment key 210 may contact an upper surface of the dummy upper electrode 200. Alternatively, in one embodiment, when the alignment key 210 extends vertically into the dummy upper electrode 200, a lower surface and a portion of the side surface of the alignment key 210 may contact the dummy upper electrode 200.

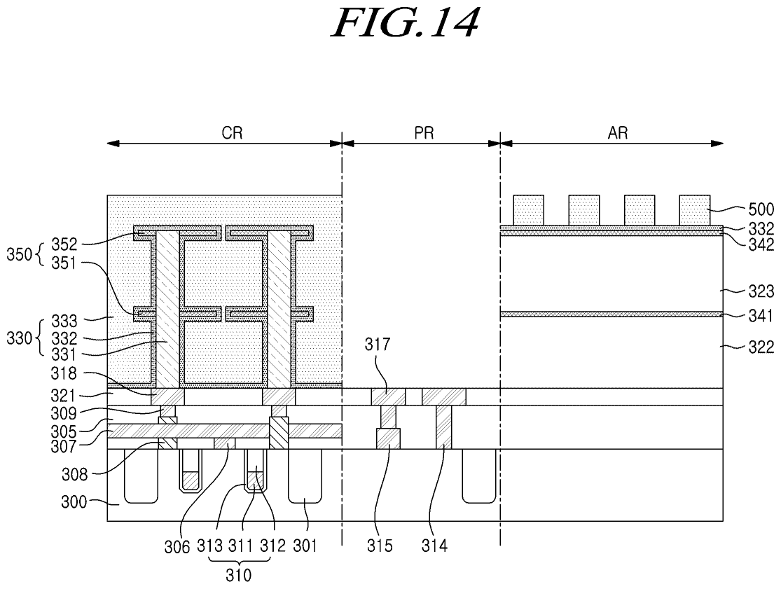

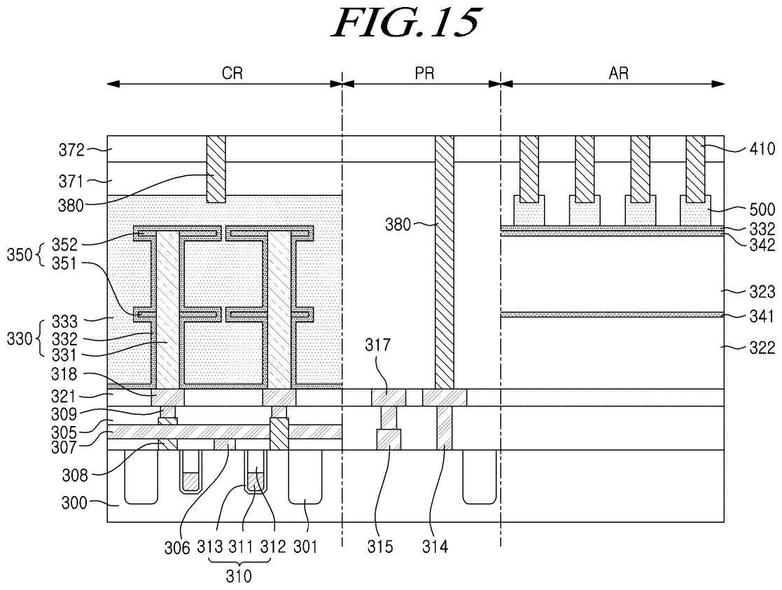

FIGS. 14 and 15 illustrate other methods for forming a memory device according to embodiments of the present disclosure.

The memory device illustrated in FIG. 14 may be formed by the same method as the manufacturing method of the memory device described with reference to FIGS. 6 to 10.

Referring to FIG. 14, a dielectric layer 332 may be formed on the first insulating layer 321, the lower electrode 331 and the support pattern layer 350 in the cell region CR, and on the second support layer 342 in the alignment key region AR. In the cell region CR, the dielectric layer 332 may be formed along a profile of the surface of the lower electrode 331 and the support pattern layer 350.

An upper electrode 333 may be formed on the dielectric layer 332 in the cell region CR and the alignment key region AR. The dielectric layer 332 and the upper electrode 333 may be removed in the peripheral region PR. A part of the upper electrode 333 formed in the alignment key region AR may be removed to form a dummy upper electrode 500. The dummy upper electrode 500 may partially expose an upper surface of the dielectric layer 332 in the alignment key region AR.

In one embodiment, the dummy upper electrode 500 may include the same material as the material forming the upper electrode 333. In one embodiment, the upper surface of the dummy upper electrode 500 may be located at substantially the same level as the upper surface of the upper electrode 333.

Referring to FIG. 15, a first interlayer insulating layer 371, a second interlayer insulating layer 372, and a through hole penetrating the first interlayer insulating layer 371 and the second interlayer insulating layer 372 may be formed in the cell region CR, the peripheral region PR and the alignment key region AR. The first interlayer insulating layer 371, the second interlayer insulating layer 372, and the through hole may be formed in substantially the same manner as the first interlayer insulating layer 371, the second interlayer insulating layer 372, and the through hole 1201 described with reference to FIGS. 12 and 13.

In the alignment key region AR, the through hole may be formed to overlap with the dummy upper electrode 500. The through hole may correspond to each dummy upper electrode 500. In an embodiment, one end of the through hole may extend into the inside of the dummy upper electrode 500 in the vertical direction. In this case, one end of the through hole may be located at a level lower than the upper surface of the dummy upper electrode 500.

In the cell region CR and the peripheral region PR, a through contact 380 may be formed in substantially the same manner as the through contact 380 described with reference to FIG. 13.

In the alignment key region AR, an alignment key 410 may be disposed to fill the through hole. A lower surface of the alignment key 410 may contact the upper surface of the dummy upper electrode 500. Alternatively, in an embodiment, when the alignment key 410 extends vertically into the dummy upper electrode 500, a lower surface and a portion of the side surface of the alignment key 410 may contact the dummy upper electrode 500.

Referring again to FIG. 3, in the alignment key region AR, the separation insulating layer 305, the first insulating layer 321, the second insulating layer 322, the first support layer 341, the third insulating layer 323, the second support layer 342, and the dielectric layer 332 may be sequentially arranged on the substrate 300. The dummy upper electrode 200 may be disposed on the dielectric layer 332, and the alignment key 210 may be disposed on the dummy upper electrode 200. In one embodiment, the dummy upper electrode 200 may include the same material as the material forming the upper electrode 333 arranged in the cell region CR. In one embodiment, the dummy upper electrode 200 may contain titanium nitride or silicon germanium.

In an embodiment different from the present disclosure, a metal layer disposed under the alignment key 210 in the alignment key region AR may include tungsten. Since tungsten has a high melting point and high hardness, the stress may accumulate in the metal layer when performing a dicing process in the scribe lane region, which may cause cracks or lifting within the metal layer. The cracks or lifting may cause dicing in an undesired direction, which may eventually cause a dividing defect.

According to embodiments of the present disclosure, the dummy upper electrode 200 disposed under the alignment key 210 in the alignment key region AR may include the same material as the material forming the upper electrode 333, for example, titanium nitride or silicon germanium. Since the material forming the upper electrode 333 has lower hardness than tungsten, when the dummy upper electrode 200 is formed with such a material, there may be reduced stress accumulated within the dummy upper electrode 200 during the dicing process. Therefore, it is possible to prevent a dividing defect that may occur due to cracks or lifting during the dicing process. In addition, since the dummy upper electrode 200 may be formed in the same process as the upper electrode 333, a separate process for forming a metal layer under the alignment key 210 is not required, so that the process can be simplified.

According to the embodiments of the present disclosure, the dummy upper electrode 200 disposed under the alignment key 210 may be arranged along the shape of an arrangement of the alignment key 210, so that it is possible to reduce the area where the dummy upper electrode 200 is disposed, thereby dicing the dummy upper electrode 200 more easily. Therefore, it is possible to effectively prevent a dividing defect of the memory device.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, since the embodiments disclosed in this disclosure are not intended to limit the technical idea of this disclosure but to describe the technical idea of this disclosure, the scope of the technical idea of this disclosure is not limited by these embodiments. The protection scope of this disclosure should be interpreted by the claims below, and all technical ideas within the equivalent scope should be interpreted as being included in the scope of the rights of this disclosure. Furthermore, the embodiments may be combined to form additional embodiments.

What is claimed is:

1. A memory device comprising:
a substrate;
a lower electrode disposed on the substrate in a chip region;
an upper electrode on the lower electrode;
a dielectric layer disposed between the lower electrode and the upper electrode;
a dummy upper electrode disposed over the substrate in a scribe lane region continuous with the chip region, and disposed at a level higher than an upper surface of the lower electrode; and
an alignment key disposed on the dummy upper electrode.

2. The memory device of claim 1, wherein the dummy upper electrode has a two-dimensional plate shape.

3. The memory device of claim 1, wherein the dummy upper electrode includes the same material as a material of the upper electrode.

4. The memory device of claim 1, wherein the dummy upper electrode includes silicon germanium or titanium nitride.

5. The memory device of claim 1, further comprising a support layer disposed between the dummy upper electrode and the substrate in the scribe lane region.

6. The memory device of claim 5, further comprising a support pattern layer surrounding a side of the lower electrode,
wherein the support layer is disposed on the same layer as the support pattern layer.

7. The memory device of claim 5, further comprising a dielectric layer disposed between the dummy upper electrode and the support layer.

8. The memory device of claim 1, wherein the dummy upper electrode is disposed along a shape in which the alignment key is arranged on a plane parallel to an upper surface of the substrate.

9. The memory device of claim 8, wherein the alignment key includes a plurality of line patterns, and the dummy upper electrode is disposed to correspond to each of the plurality of line patterns.

10. A memory device comprising:
a substrate;
a lower electrode disposed on the substrate in a chip region;
an upper electrode on the lower electrode;
a dielectric layer disposed between the lower electrode and the upper electrode; and
an alignment key disposed over the substrate scribe lane region continuous with the chip region, and positioned at a level higher than an upper surface of the lower electrode.

11. The memory device of claim 10, further comprising a dummy upper electrode disposed below the alignment key,
wherein the dummy upper electrode has a two-dimensional plate shape.

12. The memory device of claim 11, wherein the dummy upper electrode is disposed along a shape in which the alignment key is arranged on a plane parallel to an upper surface of the substrate.

13. The memory device of claim 11, wherein the dummy upper electrode includes the same material as a material of the upper electrode.

14. The memory device of claim 11, wherein the dummy upper electrode includes silicon germanium or titanium nitride.

15. The memory device of claim 10, further comprising:
a support layer disposed between the alignment key and the substrate in the scribe lane region; and
a dielectric layer disposed between the alignment key and the support layer.

16. A memory device comprising:
a substrate;
a lower electrode disposed on the substrate in a chip region;
an upper electrode on the lower electrode;
a dielectric layer disposed between the lower electrode and the upper electrode;
a support layer disposed on the substrate in a scribe lane region continuous with the chip region;
a dummy upper electrode disposed on the support layer; and
an alignment key disposed on the dummy upper electrode.

17. The memory device of claim 16, further comprising a support pattern layer surrounding the lower electrode,
wherein the support pattern layer and the support layer are disposed on the same layer.

18. The memory device of claim 16, further comprising a dielectric layer disposed between the dummy upper electrode and the support layer.

19. The memory device of claim 16, wherein the dummy upper electrode includes the same material as a material of the upper electrode.

20. The memory device of claim 16, wherein the dummy upper electrode is disposed along a shape in which the alignment key is arranged on a plane parallel to an upper surface of the substrate.
